(19) United States
(12) Patent Application Publication
(10) Pub. No.: US 2025/0393151 A1
(43) Pub. Date: Dec. 25, 2025

(54) LOCKING ASSEMBLY

(71) Applicant: Fulian Precision Electronics ( Tiajin ) Co., Ltd., Tianjin (CN)

(72) Inventor: HSUAN-AN SHIH, New Taipei (TW)

(21) Appl. No.: 18/952,963

(22) Filed: Nov. 19, 2024

(30) Foreign Application Priority Data
Jun. 24, 2024 (CN) 202410821703.4

(51) Int. Cl. H05K 7/14

(52) U.S. Cl. CPC H05K 7/1417

(57) ABSTRACT

A locking assembly includes a fixing mechanism, an elastic member, a sliding block, and a rotating member. The fixing mechanism defines a sliding groove and a receiving groove. The sliding groove extends along a first direction. The elastic member is disposed in the receiving groove. The sliding block is movably disposed in the fixing mechanism along a second direction. The sliding block includes a first blocking portion and a first protruding portion. The first protruding portion protrudes from the receiving groove along the first direction. The rotating member rotatably is disposed on the fixing mechanism. The rotating member includes a second protruding portion. The second protruding portion can rotate around the first direction and resist against the first protruding portion, such that the second protruding portion drives the sliding block to move along the second direction to compress the elastic member.

### FIELD

The subject matter herein generally relates to locking, and more particularly, to a locking assembly.

### BACKGROUND

When a board card is installed on a bracket, an end of the board card needs to be fixed with a locking assembly to prevent the board card from falling off due to vibration or impact. The board card may be manually installed on the bracket. When the board card needs to be separated from the bracket, additional force is required to maintain the locking assembly in an unlocked state. Therefore, there is a room for improvement in the art

### BRIEF DESCRIPTION OF THE DRAWINGS

Implementations of the present technology will now be described, by way of example only, with reference to the attached figures.

FIG. 1 is a diagrammatic view of a locking assembly according to an embodiment of the present disclosure.

FIG. 2 is an exploded view of the locking assembly of FIG. 1.

FIG. 3 is a diagrammatic view showing a terminal element unlocked by the locking assembly of FIG. 1.

FIG. 4 is a diagrammatic view showing the terminal element disposed in a sliding groove of the locking assembly shown in FIG. 3.

FIG. 5 is a diagrammatic view showing the terminal element sliding to a critical point where the terminal element is separated from a sliding block of the locking assembly shown in FIG. 4.

FIG. 6 is a diagrammatic view showing a rotating member of the locking assembly rotated and resisted against the sliding block shown in FIG. 5.

FIG. 7 is a diagrammatic view showing the terminal element during the process of sliding out of the sliding groove shown in FIG. 6.

FIG. 8 is a diagrammatic view showing the terminal element after sliding out of the sliding groove shown in FIG. 7.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

Some embodiments of the present disclosure will be described in detail with reference to the drawings. If no conflict, the following embodiments and features in the embodiments can be combined with each other.

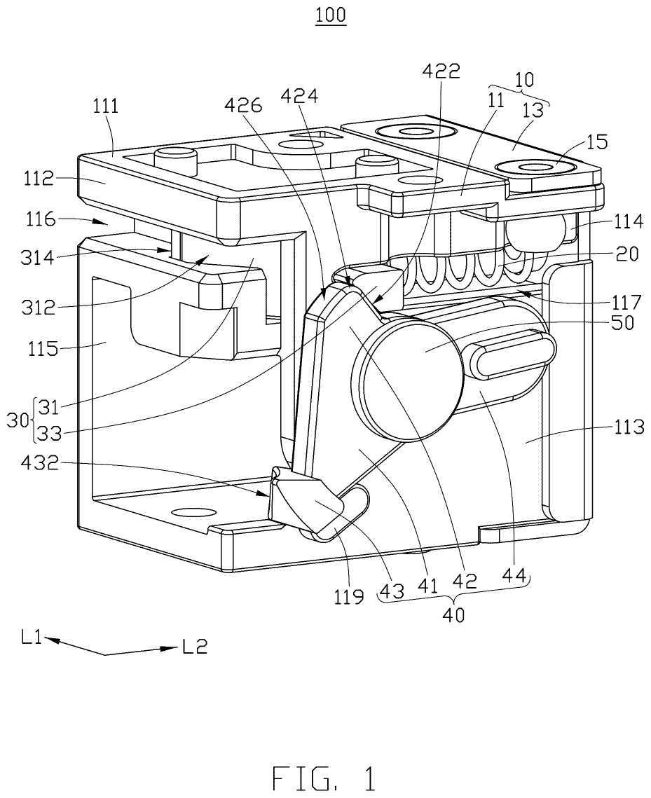

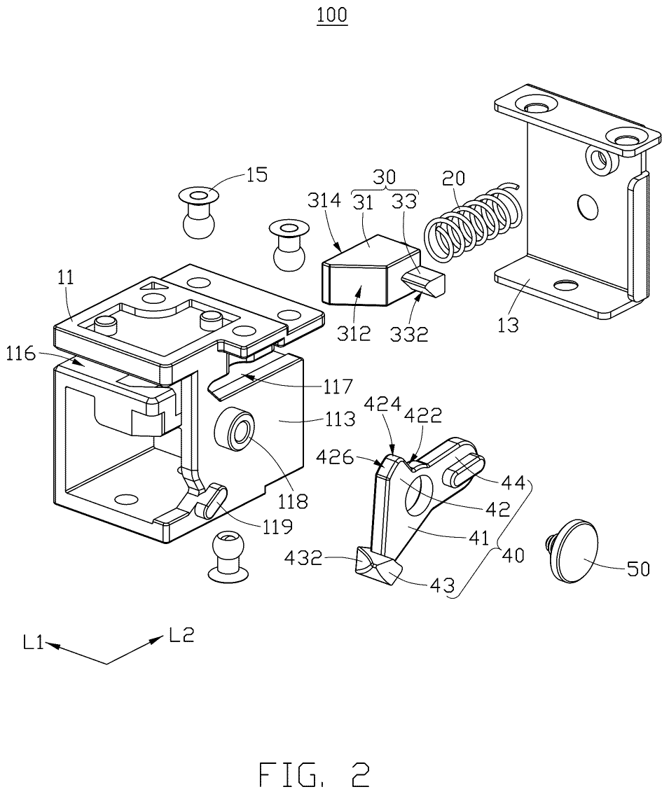

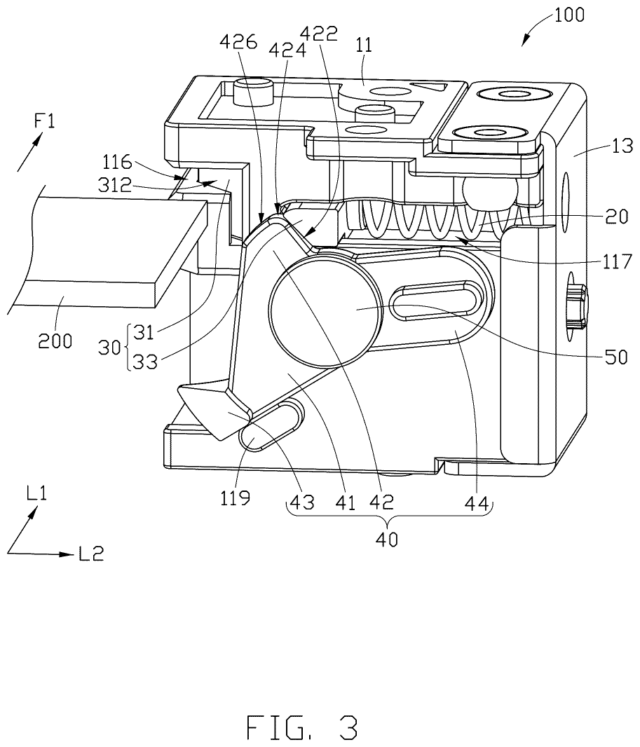

Referring to FIGS. 1 and 2, a locking assembly 100 is provided according to an embodiment of the present disclosure. The locking assembly 100 can lock a terminal element 200 (shown in FIG. 3). The terminal element 200 includes, but is not limited to, a component such as a server or a board card that needs to be detachably fixed to a bracket (not shown).

The locking assembly 100 includes a fixing mechanism 10, an elastic member 20, a sliding block 30, and a rotating member 40. The elastic member 20 is connected to the fixing mechanism 10 and the sliding block 30. The rotating member 40 is rotatably disposed on the fixing mechanism 10. When the locking assembly 100 locks the terminal element 200, the locking assembly 100 can automatic lock the terminal element 200. By rotating the rotating member 40, the locking assembly 100 is unlocked. When the terminal element 200 is separated from the locking assembly 100, the locking assembly 100 can automatically return to an original position thereof. The locking assembly 100 is easy to operate during the locking and unlocking processes.

The fixing mechanism 10 includes a base 11 and a rear cover 13. The rear cover 13 and the base 11 are fixed to each other. In the embodiment, the rear cover 13 is fixed to the base 11 through a first fixing member 15, and first fixing member 15 is a nut. In other embodiments, the rear cover 13 can be fixed to the base 11 through other fixing methods. In another embodiment, the rear cover 13 and the base 11 can be integrally formed.

The base 11 includes a top plate 111, a first side plate 112, a second side plate 113, a third side plate 114, and a fourth side plate 115. The first side plate 112, the second side plate 113, the third side plate 114, and the fourth side plate 115 are sequentially disposed around the top plate 111 and connected to the top plate 111. The first side plate 112 and the third side plate 114 are opposite to each other, and the second side plate 113 and the fourth side plate 115 are opposite to each other. The rear cover 13 is fixed to the third side plate 114.

The base 11 defines a sliding groove 116 and a receiving groove 117. The sliding groove 116 extends along a first direction L1. The sliding groove 116 is defined on the first side plate 112 and extends through the second side plate 113 and the fourth side plate 115. The sliding groove 116 and the receiving groove 117 communicate with each other. The sliding groove 116 and the receiving groove 117 are disposed along a second direction L2. The receiving groove 117 is defined on the second side plate 113 and the third side plate 114. A portion of the rear cover 13 is exposed from the receiving groove 117. The terminal element 200 can be slidably disposed in the sliding groove 116 along the first direction L1. The second direction L2 intersects with the first direction L1. In the embodiment, the second direction L2 and the first direction L1 are perpendicular to each other. In other embodiments, the base 11 and the rear cover 13 are integrally formed, and the receiving groove 117 may be considered as being defined on the second side plate 113.

The elastic member 20 is disposed in the receiving groove 117. One end of the elastic member 20 is connected to the rear cover 13, and another end of the elastic member 20 is connected to the sliding block 30. The elastic member 20 can deform along the second direction L2. In the embodiment, the elastic member 20 is a spring.

The sliding block 30 is movably disposed in the fixing mechanism 10 along the second direction L2. The sliding block 30 includes a first blocking portion 31 and a first protruding portion 33 fixed to the first blocking portion 31. One side of the first blocking portion 31 is connected to the elastic member 20, and the first blocking portion 31 can move into the receiving groove 117 along the second direction L2 to compress the elastic member 20. A side of the first blocking portion 31 opposite to the elastic member 20 can be disposed in the sliding groove 116. The first protruding portion 33 protrudes from the receiving groove 117 along the first direction L1.

The first blocking portion 31 includes a first inclined surface 312 and a blocking surface 314 opposite to the first inclined surface 312. The first inclined surface 312 intersects with each of the first direction L1 and the second direction L2. The blocking surface 314 is opposite to the first protruding portion 33. The blocking surface 314 is parallel to the second direction L2. When the terminal element 200 slides along the sliding groove 116, the terminal element 200 is first in contact with the first inclined surface 312 and gradually resists against the first blocking portion 31, causing the first blocking portion 31 to move along the second direction L2 to compress the elastic member 20. Due to the first inclined surface 312, when the terminal element 200 moves along the first direction L1, the sliding block 30 can smoothly move along the second direction L2.

When the locking assembly 100 is in a locked state, the sliding block 30 returns to the original position under a rebounding force of the elastic member 20, a portion of the first blocking portion 31 is disposed in the sliding groove 116, and the blocking surface 314 is disposed on one side of the terminal element 200, thereby limiting a movement of the terminal element 200. In the embodiment, each of the first inclined surface 312 and the blocking surface 314 can be flat.

The first protruding portion 33 includes a pressing surface 332. The pressing surface 332 faces the rotating member 40. The pressing surface 332 is parallel to the first direction L1 and intersects with the second direction L2. The pressing surface 332 can be in contact with the rotating member 40.

The rotating member 40 is rotatably disposed on the second side plate 113 around the first direction L1. The rotating member 40 includes a main body 41, a second protruding portion 42, a second blocking portion 43, and a handle portion 44. The second side plate 113 is provided with a fixing portion 118 protruding along the first direction L1. The fixing portion 118 is columnar. The main body 41 is approximately disc-shaped. The main body 41 is rotatably sleeved on the fixing portion 118. The locking assembly 100 further includes a second fixing member 50. The second fixing member 50 is fixed to a side of the fixing portion 118 opposite to the main body 41. The second fixing member 50 can limit the rotating member 40 on the fixing portion 118. The second protruding portion 42, the second blocking portion 43, and the handle portion 44 all extend radially from a circumference of the main body 41 and are spaced apart from each other. A force can be applied to the handle portion 44 to rotate the rotating member 40. The first protruding portion 33 is disposed within a rotating path of the second protruding portion 42. The second protruding portion 42 can drive the first protruding portion 33 to move along the second direction L2. An end of the sliding groove 116 near the second side plate 113 is disposed within a rotating path of the second blocking portion 43. The second blocking portion 43 can return back when the terminal element 200 slides out of the sliding groove 116.

The second protruding portion 42 includes a first contacting surface 422, an arc surface 424, and a second contacting surface 426. The arc surface 424 is connected to the first contacting surface 422 and the second contacting surface 426. Each of the first contacting surface 422, the arc surface 424, and the second contacting surface 426 is parallel to the first direction L1. The first contacting surface 422 is a surface of the second protruding portion 42 near the handle portion 44. The second contacting surface 426 is a surface opposite to the handle portion 44. Each of the first contacting surface 422, the arc surface 424, and the second contacting surface 426 is used for slidably connecting to the pressing surface 332.

When the force is applied to the handle portion 44 to rotate the rotating member 40, the second protruding portion 42 rotates and is in contact with the pressing surface 332, driving the first protruding portion 33 to move along the second direction L2, thereby driving the first blocking portion 31 to move along the second direction L2 and return back from the sliding groove 116 into the receiving groove 117. At the time, the first blocking portion 31 compresses the elastic member 20 along the second direction L2. During the rotation of the rotating member 40, the first contacting surface 422, the arc surface 424, and the second contacting surface 426 are sequentially in contact with the pressing surface 332.

An end of the second blocking portion 43 opposite to the main body 41 is provided with a second inclined surface 432. The second inclined surface 432 faces the base 11 and intersects with each of the first direction L1 and the second direction L2. An end of the sliding groove 116 is disposed within a rotating path of the second inclined surface 432. When the second blocking portion 43 rotates, the second inclined surface 432 can expose from the sliding groove 116. In the embodiment, the second inclined surface 432 is curve. When unlocking the locking assembly 100, the terminal element 200 is first in contact with the second inclined surface 432 and gradually resists against the second blocking portion 43, causing the second blocking portion 43 to rotate around the first direction L1. Due to the second inclined surface 432, when the terminal element 200 moves along the first direction L1, the rotating member 40 can smoothly rotate around the first direction L1.

The base 11 further includes a stopping portion 119. The stopping portion 119 is disposed on the second side plate 113 and protrudes from the second side plate 113 along the first direction L1. The stopping portion 119 is disposed within rotating paths of the second blocking portion 43 and the handle portion 44, and the stopping portion 119 can limit the movement of the second blocking portion 43 and the handle portion 44.

Referring to FIGS. 3 to 8, a further explanation of the components and functions of the locking assembly 100 of the present disclosure is illustrated through the locking and unlocking processes.

Referring to FIG. 3, when the locking assembly 100 is unlock to the terminal element 200, the two ends of the elastic member 20 resist against the rear cover 13 and the first blocking portion 31. A portion of the first blocking portion 31 is disposed in the sliding groove 116. At the time, the locking assembly 100 is in an original state.

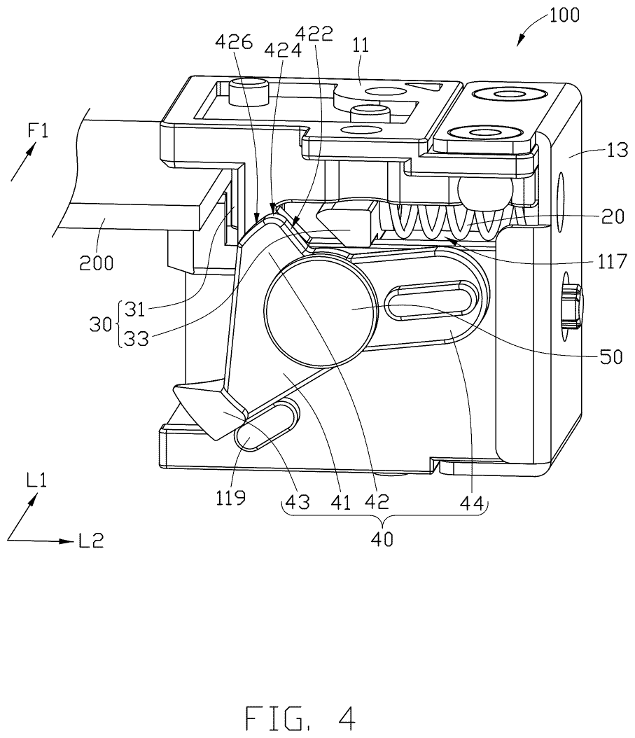

Referring to FIG. 4, when the terminal element 200 locks the locking assembly 100, one side of the terminal element 200 is disposed in the sliding groove 116. A force F1 is applied to the terminal element 200 and push the terminal element 200 to slide along the first direction L1. During the sliding process, the terminal element 200 is first in contact with the first inclined surface 312 of the first blocking portion 31 and gradually resists against the first blocking portion 31, causing the first blocking portion 31 to move along the second direction L2 to compress the elastic member 20, thus the elastic member 20 deforms along the second direction L2.

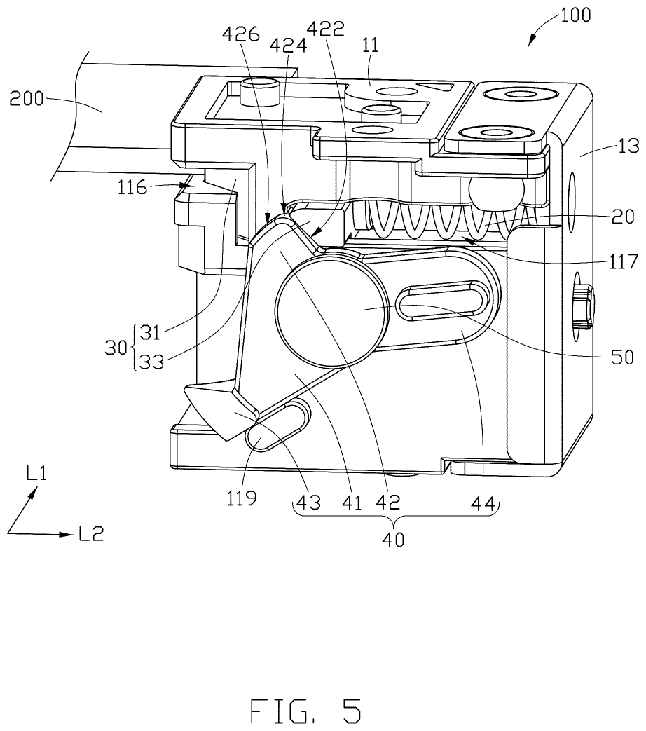

Referring to FIG. 5, as the terminal element 200 continues to slide until the terminal element 200 reaches a critical point where the terminal element 200 separates from the first blocking portion 31 (a preset position of the terminal element 200 in the sliding groove 116), the first blocking portion 31 loses the force exerted by the terminal element 200. At the time, the sliding block 30 returns to the original position under the rebounding force of the elastic member 20. The sliding block 30 is driven by the elastic member 20 to move along the second direction L2 towards the sliding groove 116, until a portion of the first blocking portion 31 is disposed in the sliding groove 116 and the blocking surface 314 of the first blocking portion 31 is disposed on one side of the terminal element 200, thereby limiting the movement of the terminal element 200. During the automatic locking process of the locking assembly 100 to the terminal element 200, it is only necessary to apply the force to the terminal element 200, without additional force to the locking assembly 100. The automatic locking mechanism of the locking assembly 100 can prevent users from forgetting the locking step.

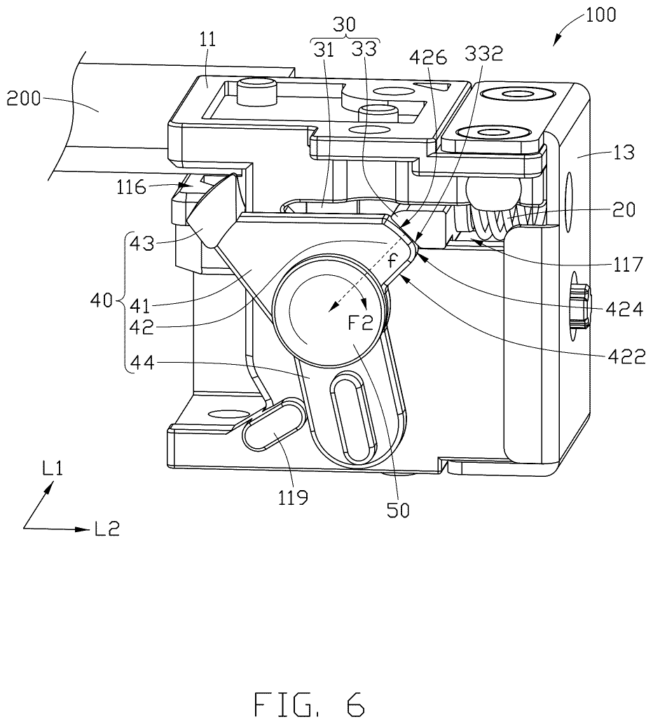

Referring to FIG. 6, when the locking assembly 100 is unlocked, a force F2 is applied to the rotating member 40 to rotate the rotating member 40. During the rotation of the rotating member 40, the second protruding portion 42 resists against the first protruding portion 33, driving first protruding portion 33 to move along the second direction L2 to compress the elastic member 20, the first contacting surface 422, the arc surface 424, and the second contacting surface 426 are sequentially in contact with the pressing surface 332. The first blocking portion 31 moves synchronously with the first protruding portion 33, thereby releasing the terminal element 200. At the time, the second inclined surface 432 of the second blocking portion 43 is exposed from the sliding groove 116. When the second contacting surface 426 resists against the pressing surface 332, the pressing surface 332 exerts a force F towards a rotational center of the rotating member 40 on the second contacting surface 426, the force F can counteract at least a portion of the rebounding force of the elastic member 20. When the force F2 is withdrawn, the sliding block 30 can temporarily be in a stationary state, preventing the sliding block 30 from resetting, allowing the user to free both hands to apply force to the terminal element 200 and the bracket at the time.

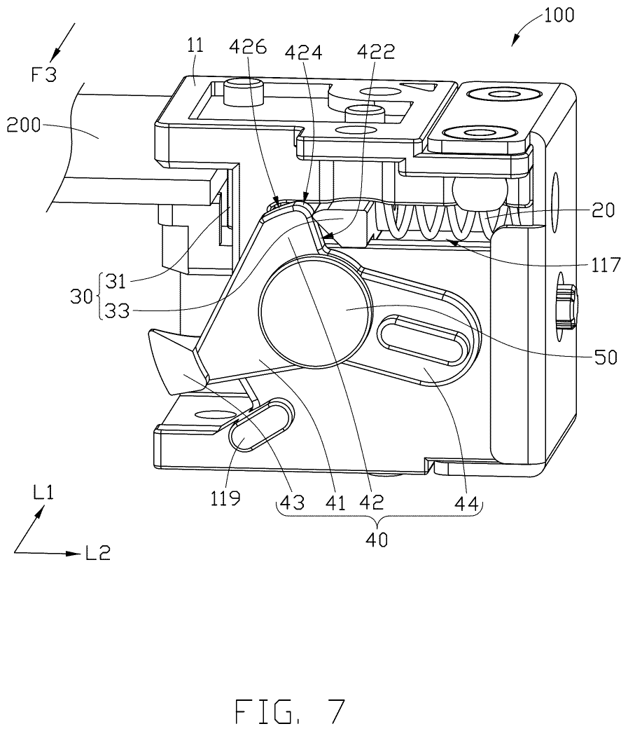

Referring to FIG. 7, a force F3 is applied to the terminal element 200 to slide out of the sliding groove 116. The terminal element 200 is first in contact with the second inclined surface 432 and gradually resists against the second blocking portion 43, causing the second blocking portion 43 to rotate around the first direction L1. When the second blocking portion 43 rotates, the second protruding portion 42 rotates synchronously to release the sliding block 30, and the sliding block 30 then moves towards the sliding groove 116 under the rebounding force of the elastic member 20.

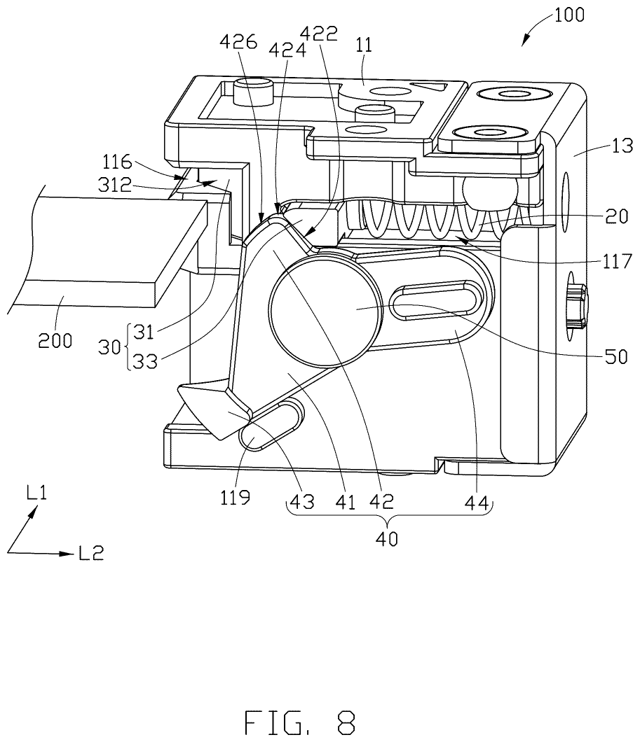

Referring to FIG. 8, after the terminal element 200 slides out of the sliding groove 116, the terminal element 200 no longer limits the movement of the sliding block 30, and the sliding block 30 returns to original position under the rebounding force of the elastic member 20.

When the locking assembly 100 locks the terminal element 200, the terminal element 200 slides to the preset position in the sliding groove 116, and then the sliding block 30 returns to the original position under the rebounding force of the elastic member 20, allowing the locking assembly 100 can automatic lock the terminal element 200. When unlocking the locking assembly 100, the rotating member 40 is unlocked to unlock the terminal element 200, and the rotating member 40 has the temporary limiting effect on the sliding block 30, so that the user has no need to hold the sliding block 30. After the terminal element 200 is separated from the locking assembly 100, the locking assembly 100 can automatically return to its original position. The locking assembly 100 is easy to operate during both the locking and unlocking processes, providing convenience for the user.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A locking assembly comprising:
a fixing mechanism defining a sliding groove and a receiving groove, the sliding groove extending along a first direction, the sliding groove and the receiving groove communicating with each other;
an elastic member disposed in the receiving groove;
a sliding block movably disposed in the fixing mechanism along a second direction, the sliding block comprising a first blocking portion and a first protruding portion fixed to the first blocking portion, the sliding block configured to move into the receiving groove along the second direction to compress the elastic member, the first protruding portion protruding from the receiving groove along the first direction; and
a rotating member rotatably disposed on the fixing mechanism around the first direction, the rotating member comprising a second protruding portion, the second protruding portion configured to rotate around the first direction and resist against the first protruding portion, such that the second protruding portion drives the sliding block to move along the second direction to compress the elastic member.

2. The locking assembly of claim 1, wherein the first blocking portion comprises a first inclined surface and a blocking surface opposite to the first inclined surface, the blocking surface is opposite to the first protruding portion, and the first inclined surface intersects with each of the first direction and the second direction.

3. The locking assembly of claim 1, wherein the rotating member further comprises a main body, the second protruding portion extends radially from a circumference of the main body, the main body is rotatably sleeved on the fixing mechanism, and the first protruding portion is disposed within a rotating path of the second protruding portion.

4. The locking assembly of claim 3, wherein the second protruding portion comprises a first contacting surface, an arc surface, and a second contacting surface, the arc surface is connected to the first contacting surface and the second contacting surface, each of the first contacting surface, the arc surface, and the second contacting surface is parallel to the first direction and configured to slidably connect to the first protruding portion; when a portion of the first protruding portion is disposed in the sliding groove, the first protruding portion is connected to the first contacting surface.

5. The locking assembly of claim 4, wherein the first protruding portion comprises a pressing surface, the pressing surface is parallel to the first direction and intersects with the second direction, and the pressing surface is configured to be in contact with the first contacting surface, the arc surface, and the second contacting surface.

6. The locking assembly of claim 3, wherein the rotating member further comprises a second blocking portion, the second blocking portion extends radially from the circumference of the main body and is spaced apart from the second protruding portion, and an end of the sliding groove near the fixing mechanism is disposed within a rotating path of the second blocking portion.

7. The locking assembly of claim 4, wherein the rotating member further comprises a second blocking portion, the second blocking portion extends radially from the circumference of the main body and is spaced apart from the second protruding portion, and an end of the sliding groove near the fixing mechanism is disposed within a rotating path of the second blocking portion.

8. The locking assembly of claim 5, wherein the rotating member further comprises a second blocking portion, the second blocking portion extends radially from the circumference of the main body and is spaced apart from the second protruding portion, and an end of the sliding groove near the fixing mechanism is disposed within a rotating path of the second blocking portion.

9. The locking assembly of claim 3, wherein the second blocking portion comprises a second inclined surface, the second inclined surface faces the fixing mechanism and intersects with each of the first direction and the second direction, and an end of the sliding groove is disposed within a rotating path of the second inclined surface.

10. The locking assembly of claim 6, wherein the rotating member further comprises a handle portion, and the handle portion extends radially from the circumference of the main body and is spaced apart from the second blocking portion.

11. The locking assembly of claim 6, wherein the fixing mechanism further comprises a stopping portion, the stopping portion is disposed within rotating paths of the second blocking portion and the handle portion, and the stopping portion is configured to limit each of the second blocking portion and the handle portion.

12. The locking assembly of claim 1, wherein the fixing mechanism further comprises a base and a rear cover, the sliding groove and the receiving groove are defined on the base, a portion of the rear cover is exposed from the receiving groove, and two ends of the elastic member are connected to the rear cover rear cover and the sliding block.

13. The locking assembly of claim 1, wherein the fixing mechanism further comprises a base and a rear cover, the sliding groove and the receiving groove are defined on the base, a portion of the rear cover is exposed from the receiving groove, and two ends of the elastic member are connected to the rear cover rear cover and the sliding block.

14. The locking assembly of claim 2, wherein the fixing mechanism further comprises a base and a rear cover, the sliding groove and the receiving groove are defined on the base, a portion of the rear cover is exposed from the receiving groove, and two ends of the elastic member are connected to the rear cover rear cover and the sliding block.

15. The locking assembly of claim 3, wherein the fixing mechanism further comprises a base and a rear cover, the sliding groove and the receiving groove are defined on the base, a portion of the rear cover is exposed from the receiving groove, and two ends of the elastic member are connected to the rear cover rear cover and the sliding block.

16. The locking assembly of claim 4, wherein the fixing mechanism further comprises a base and a rear cover, the sliding groove and the receiving groove are defined on the base, a portion of the rear cover is exposed from the receiving groove, and two ends of the elastic member are connected to the rear cover rear cover and the sliding block.

17. The locking assembly of claim 5, wherein the fixing mechanism further comprises a base and a rear cover, the sliding groove and the receiving groove are defined on the base, a portion of the rear cover is exposed from the receiving groove, and two ends of the elastic member are connected to the rear cover rear cover and the sliding block.

18. The locking assembly of claim 9, wherein the fixing mechanism further comprises a base and a rear cover, the sliding groove and the receiving groove are defined on the base, a portion of the rear cover is exposed from the receiving groove, and two ends of the elastic member are connected to the rear cover rear cover and the sliding block.

19. The locking assembly of claim 10, wherein the fixing mechanism further comprises a base and a rear cover, the sliding groove and the receiving groove are defined on the base, a portion of the rear cover is exposed from the receiving groove, and two ends of the elastic member are connected to the rear cover rear cover and the sliding block.

20. The locking assembly of claim 11, wherein the fixing mechanism further comprises a base and a rear cover, the sliding groove and the receiving groove are defined on the base, a portion of the rear cover is exposed from the receiving groove, and two ends of the elastic member are connected to the rear cover rear cover and the sliding block.
